(19) United States
(12) Patent Application Publication
(10) Pub. No.: US 2019/0229649 A1
(43) Pub. Date: Jul. 25, 2019

(54) HYDROKINETIC POWER GENERATION SYSTEM

(71) Applicants: Kiarash Alizadeh, Tehran (IR); Sasan Asiaei, Tehran (IR)

(72) Inventors: Kiarash Alizadeh, Tehran (IR); Sasan Asiaei, Tehran (IR)

(21) Appl. No.: 15/876,170

(22) Filed: Jan. 21, 2018

(51) Int. Cl. H02N 11/00; H01L 29/16; H01L 29/45; H01L 29/84; H01L 27/08

(52) U.S. Cl. CPC H02N 11/002; H01L 29/1608; H01L 29/872; H01L 29/84; H01L 27/0814; H01L 29/45

(57) ABSTRACT

A hydrokinetic power generation system for harnessing hydrokinetic energy from hydrokinetic energy sources using semiconductor device is disclosed. The semiconductor device comprises at least one of a PN junction or Schottky contact. The semiconductor device is configured to immerse in an electrolytic fluid stream such that the PN junction or the Schottky contact is adapted to be in contact with the electrolytic fluid stream. The device enables conversion of kinetic energy of the electrolytic fluid stream to electrical energy when the electrolytic fluid stream impinges upon the device at the vicinity of the PN junction or Schottky contact. The existence of non-zero velocity field in the electrolytic fluid medium at the interaction place of the semiconductor device, ensure the energy conversion and power generation. Herein all of earth's surface water types like ocean, rivers, lakes and generally every fluids have electrolytic behaviour, since there is no strictly non-electrolyte fluid. A conductive electrode is embedded to the semiconductor device to transfer the electrical energy from the device.

### BACKGROUND OF THE INVENTION

Hydrokinetic energy is a renewable energy source available in earth's surface water. The randomness of the hydrodynamic behavior of surface waters such as ocean waves is the main challenge in design and manufacturing of the energy converter devices. This challenge has led to converters that have been presented around the world with several problems including the construction cost, installation and maintenance of large dimensions and complexity of design.

General converter devices consist of two critical mechanisms, which involve conversion of non-uniform fluid motion into rotational or linear motion and transfer of mechanical power to the generator for generation of electrical power base on Faraday's law of induction. Requiring these two mechanisms is a leading cause of increase in size, weight and reduction in efficiency according to cost per power generated. The foregoing discussed issue reduces the ability of such converter devices in economic competition with other available electric power generation methods. Due to the technical nature and design requirements, inevitably most of these converters are established on the water surface that leads to disorders in landscape and maritime transportation.

A prior art US 20170198401 of Reed E. Phillips discloses a wave energy converter configured to convert oscillatory motion of waves to generate electricity. However, this type of device requires wave induced water flow for generation of electricity and cannot be utilized in variety of surface water such as lakes. Further, when wave energy is not present or doesn't match to desired amount, these prior devices utilizes battery or some other intermediary mechanisms for generating electricity, resulting in more complex designs.

One of the problems with the latest technologies is the need to customizing device according to wave characteristics for operation of a device and can be limited in application as it cannot be utilized in variety of water surfaces such as lakes, deeper water, sea bed, and/or rivers. Herein forth, there is a clear and present need for a system for harnessing hydrokinetic energy from hydrokinetic energy sources using semiconductor device, which could be utilized in a variety of water surfaces without employing a complex design or disturbing the natural landscape and marine transport.

### SUMMARY OF THE INVENTION

The present invention relates to a system for harnessing hydrokinetic energy from hydrokinetic energy sources using semiconductor device.

In an embodiment, the system comprises a semiconductor device, which is configured to convert energy of electrolytic fluid stream having non-zero velocity field to electric power, at the contact of electrolytic fluid stream and semiconductor device. In an embodiment, the electrolytic fluid stream is an earth's surface water (e.g. sea/ocean water, river and lake) or any other kind of electrolytic fluid stream. In another embodiment, the electrolytic fluid is any type of fluid. In one embodiment, the semiconductor device comprises a P-type semiconductor layer, a N-type semiconductor layer and a PN junction layer separating the P-type semiconductor layer and the N-type semiconductor layer. In another embodiment, the semiconductor device comprises a metal layer, a semiconductor layer and a Schottky contact separating the metal layer and the semiconductor layer. The semiconductor device is configured to immerse in an electrolytic fluid stream such that the PN junction or the Schottky contact is adapted to be in contact with the electrolytic fluid stream. The device enables conversion of kinetic energy of the fluid stream to electrical energy when the electrolytic fluid stream impinges upon the device at the vicinity of the PN junction or Schottky contact. The system further comprises an insulating layer.

The system further comprises a conductive electrode coupled to the semiconductor device to conduct electrical energy generated by the semiconductor device and an ammeter connected in series between the conductive electrode and the electrical load, which is configured to measure the generated electrical energy.

One aspect of the present disclosure is directed to a system for harvesting hydrokinetic energy, comprising (a) a semiconductor device having a P-type semiconductor layer, a N-type semiconductor layer and a PN junction separating the P-type semiconductor layer and the N-type semiconductor layer, wherein the device is configured to immerse in an fluid stream such that the PN junction is adapted to be in contact with the fluid stream having a non-zero velocity field, wherein the device enables conversion of kinetic energy of the fluid stream to electrical energy when the fluid stream impinges upon the device, at the vicinity of the PN junction; and (b) a conductive electrode embedded to the semiconductor device is configured to conduct electrical energy generated by the semiconductor device.

In one embodiment, the system further comprises an insulating layer. In another embodiment, the conductive electrode is coupled to an electrical load to receive the generated electrical energy. In one embodiment, the system for harvesting hydrokinetic energy further comprises an ammeter connected in series between the electrical load and the conductive electrode to measure the generated electrical energy. In one embodiment, the fluid stream is an electrolytic fluid stream. In one embodiment, the fluid stream is an earth's surface water (e.g. sea/ocean water, river and lake) or any other kind of electrolytic fluid stream. In another embodiment, the conductive electrode is made of copper. In one embodiment, the plurality of semiconductor devices are configured to connect in series and parallel arrays.

Another aspect of the present disclosure is directed to a system for harvesting hydrokinetic energy, comprising (a) a semiconductor device having a metal layer, a semiconductor layer and a Schottky contact separating the metal layer and the semiconductor layer, wherein the device is configured to immerse in an electrolytic fluid stream such that the Schottky contact is adapted to be in contact with the electrolytic fluid stream having a non-zero velocity field, wherein the device enables conversion of kinetic energy of the fluid stream to electrical energy when the fluid stream impinges upon the device, at the vicinity of the Schottky contact; and (b) a conductive electrode connected to the semiconductor device to conduct electrical energy generated by the semiconductor device.

In one embodiment, the metal layer is made of copper. In another embodiment, for making schottky contact with the semiconductor, the metal layer can be any conducting metal, material or alloy, including for example, copper, platinum and gold or any combination thereof. In another embodiment, the semiconductor layer is a P-type semiconductor layer. In one embodiment, the semiconductor layer is a N-type semiconductor layer. In another embodiment, the semiconductor layer is made of silicon carbide. In another embodiment, the electrolytic fluid stream is a sea water. In a system according to another aspect of the present disclosure, a plurality of example semiconductor devices are configured to connect in series and parallel arrays.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### BRIEF DESCRIPTION OF DRAWINGS

FIG. 1 illustrates a perspective view of a semiconductor device including a PN junction, according to one embodiment;

FIG. 2 illustrates a perspective view of a semiconductor device including a Schottky contact, according to another embodiment;

FIG. 3 illustrates a perspective view of a semiconductor device coupled with electrical circuit elements, according to an embodiment;

FIG. 4A shows a top view of functional layers of a semiconductor device, according to another embodiment;

FIG. 4B shows a perspective view of functional layers of a semiconductor device, according to another embodiment;

FIG. 5 shows a sectional view of the semiconductor device converting the kinetic energy of an electrolytic fluid stream in contact with the device;

FIG. 6 shows a schematic electric circuit made by integration of plurality of semiconductor device, according to another embodiment;

FIG. 7 shows a plurality of semiconductor device connected in series and parallel arrays immersed in the electrolytic fluid stream, according to another embodiment;

FIG. 8 is a graph of voltage-current characteristics of semiconductor device of FIG. 1 or FIG. 2;

FIG. 9 is a graph of voltage-current characteristics of the semiconductor device of FIG. 5.

### DETAILED DESCRIPTION

A description of embodiments of the present invention will now be given with reference to the figures. It is expected that the present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

The present invention generally relates to extraction of renewable energy from hydrokinetic energy sources, and more particularly relates to a system for harnessing hydrokinetic energy from hydrokinetic energy sources using semiconductor device.

The present invention relates to a semiconductor device for harnessing hydrokinetic energy from hydrokinetic energy sources. In an embodiment, the semiconductor device comprises at least one of a metal-semiconductor junction or semiconductor-semiconductor junction. The semiconductor device is configured to immerse in an electrolytic fluid stream such that the metal-semiconductor or semiconductor-semiconductor junction is adapted to be in contact with the electrolytic fluid stream having non-zero velocity field. The device enables conversion of kinetic energy of the fluid stream to electrical energy when the electrolytic fluid stream impinges upon the device at the vicinity of the metal-semiconductor or semiconductor-semiconductor junction. Further, a conductive electrode is embedded to the semiconductor device to transfer the electrical energy to the consumer. As described herein, “electrolytic fluid stream” refers to random disturbances of electrolytic fluid such as water from sea or ocean.

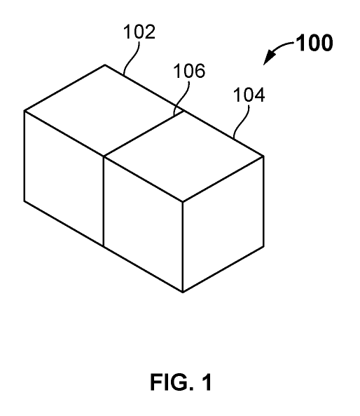

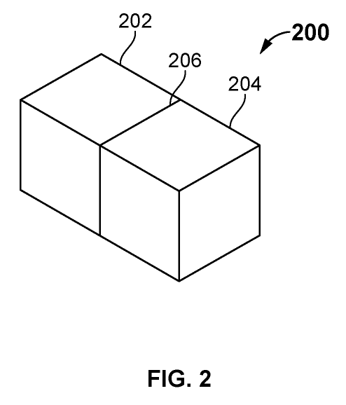

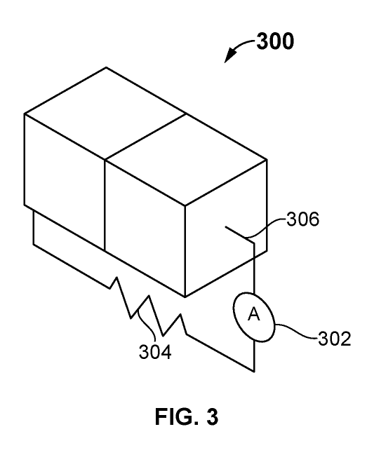

According to an embodiment of the invention as shown in FIG. 1, a perspective view of a semiconductor device 100 is disclosed. In one embodiment, the semiconductor device 100 is composed of a P-type semiconductor layer 102, a N-type semiconductor layer 104 and a PN junction 106 separating the P-type semiconductor layer 102 and the N-type semiconductor layer 104. In another embodiment as shown in FIG. 2, the semiconductor device 200 comprises a metal layer 202 and a semiconductor layer 204 and a Schottky contact 206 separating the metal layer 202 and the semiconductor layer 204.

In an embodiment, the semiconductor device is configured to be placed into the electrolytic fluid stream such the PN junction or Schottky contact is adapted to be in contact with the electrolytic fluid stream. According to the present invention, the device induced by streaming potential at the solid-fluid interface enables conversion of kinetic energy of the fluid stream to electrical energy when the fluid impinges upon the device, at the vicinity of the Schottky contact or PN junction. According to the present invention, the energy conversion occurs due to the contact of the solid object i.e., semiconductor device with the moving electrolytic fluid stream at the place of the Schottky contact or PN junction. The existence of non-zero velocity field in the electrolytic fluid medium at the interaction place with the semiconductor device, ensure the energy conversion and power generation.

Referring to FIG. 3, in an embodiment, the semiconductor device 300 is coupled with electrical circuit elements such as an ammeter 302 and an electrical resistance 304 for transferring the electrical energy to the consumer. A conductive electrode 306 embedded in the semiconductor device 300 is coupled to the electrical load or electrical resistance 304. Further, the ammeter 302 is coupled in series between the conductive electrode 306 and the electrical resistance 304 to measure the electrical energy form the conductive electrode 306.

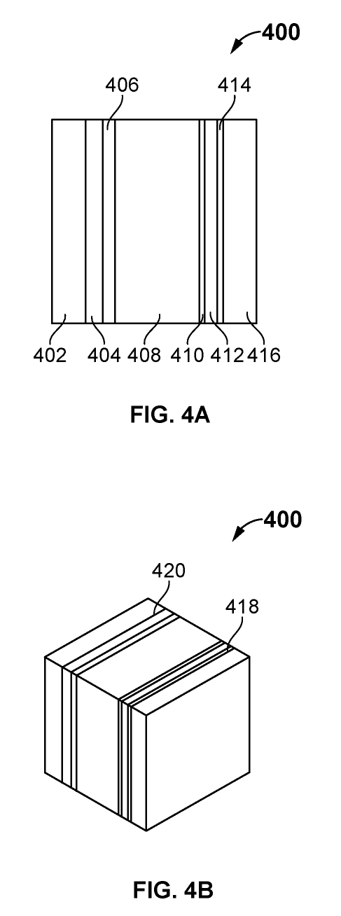

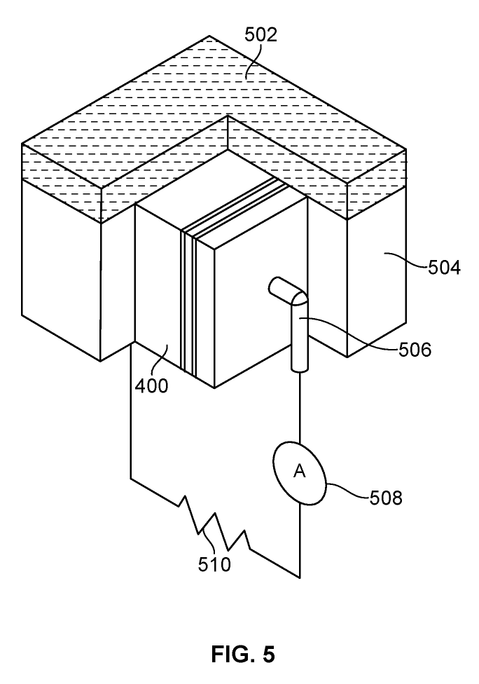

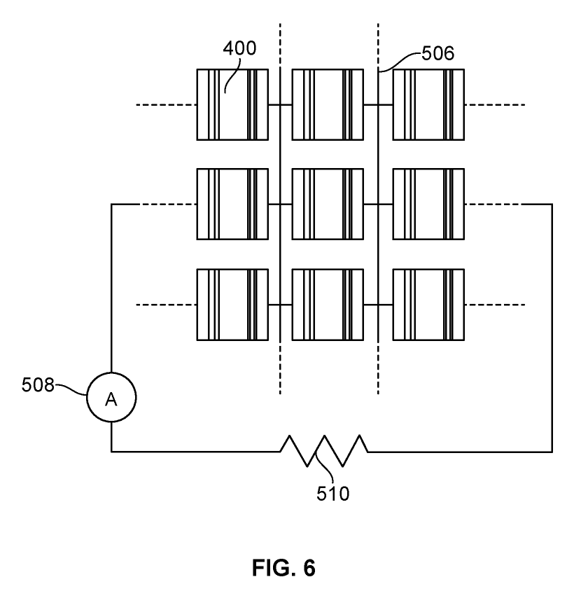

In one embodiment, a structure of the semiconductor device 400 is disclosed as shown in FIG. 4A. The semiconductor device 400 comprises a metal layer made of copper, a semiconductor layer made of silicon carbide. According to the present invention, a n− lightly doped SiC (silicon carbide) layer 404 with a content value equal to the order of 1×10¹⁶ per cubic cm is formed in contact with a copper layer 402. A n+ heavily doped SiC layer 406 with a content value equal to the order of 1×10¹⁸ per cubic cm is disposed in contact with the n− lightly doped SiC layer 404. A n+ heavily doped SiC layer 408 with a content value greater than 10¹⁸ per cubic cm is formed in contact with n+ heavily doped SiC layer 406.

A Ti (Titanium) layer 410 is formed in contact with the n+ heavily doped SiC layer 408 with a content value greater than 10¹⁸ per cubic cm. A NiGa (Nickel-Gallium) layer 412 is formed in contact with the Ti layer 410. Further, a Ti layer 414 is formed in contact with the NiGa layer 412. Referring FIG. 4B, the interface of the cu layer 402 and the n− lightly doped SiC layer 404 form a Schottky contact 420. The interface of Ti layer 414 and NiGa layer 412 forms a ohmic contact 418. The interface of Ti layer 414 and Al layer 416 forms an ohmic layer, which for example can be composed of aluminum or other suitable material, as shown in FIG. 4A.”

FIG. 5 illustrates a sectional view of the semiconductor device 400 deployed into the electrolytic fluid stream 502. A conductive electrode 506 embedded in the semiconductor device 400 is electrically connected to the electrical circuit elements such as ammeter 508 and electrical resistance 510 for transfer of electrical energy to the consumer. The semiconductor device 400 is configured to convert the kinetic energy of the electrolytic fluid stream 502 in contact with the semiconductor device 400. Further, the generated electrical energy is transferred to the electrical resistance 510 via the conductive electrode 506. In one embodiment, the conductive electrode 506 is a copper electrode. The ammeter 508 is connected in series between the electrical resistance 510 and the conductive electrode 506. The semiconductor device 400 further comprises a silicon dioxide layer 504.

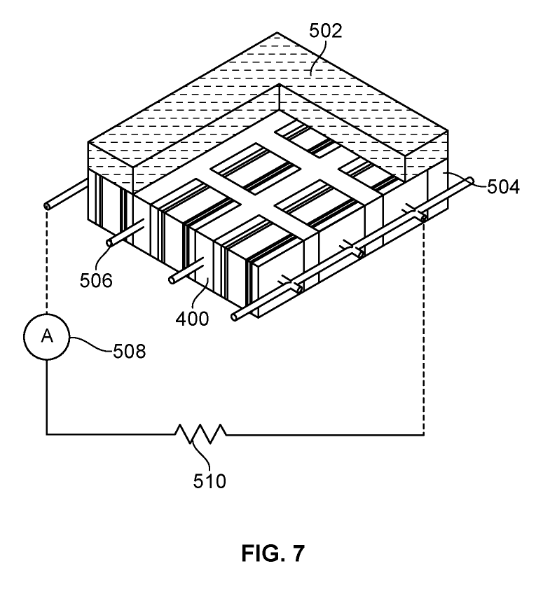

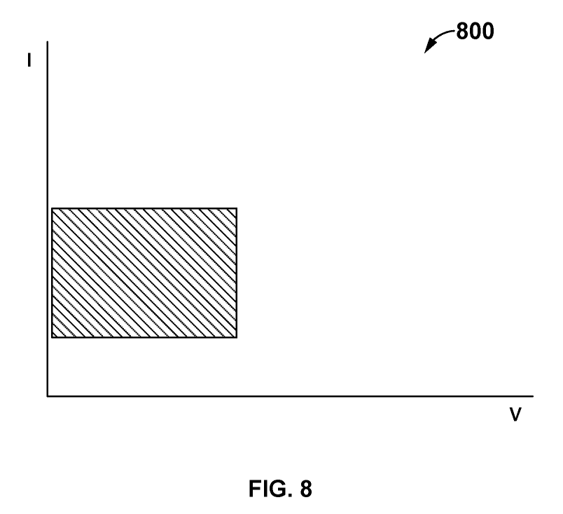

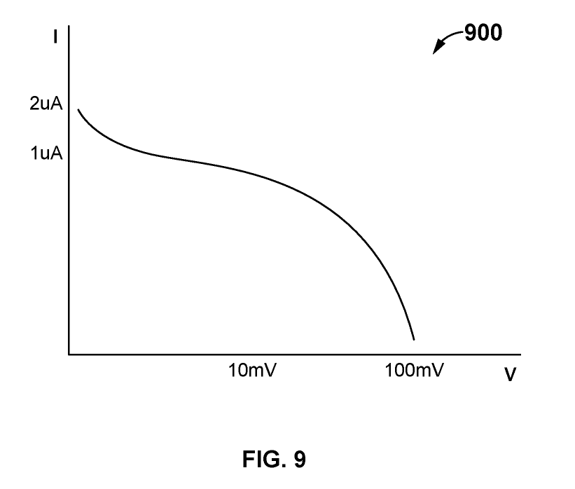

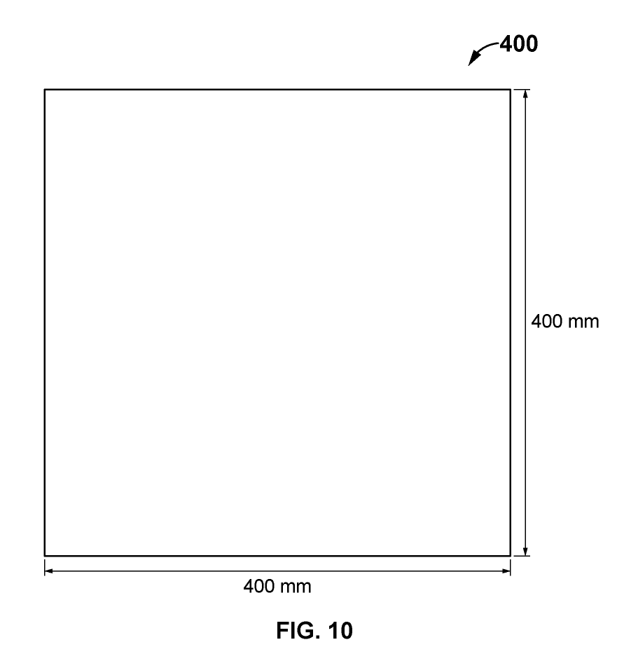

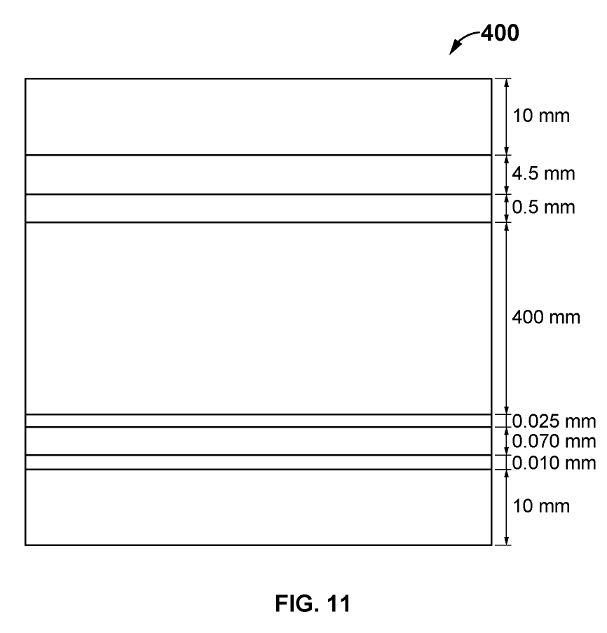

According to FIG. 6, in one embodiment, a plurality of semiconductor device 400 could be connected in series and parallel arrays, which is configured to generate more than 150 watts per cubic meter of the volume occupied by the semiconductor device 400. FIG. 7 illustrates a plurality of semiconductor device 400 connected in series and parallel arrays immersed in the electrolytic fluid stream 502. FIG. 8 is a graph 800 of voltage-current characteristics when the semiconductor device 100 or 200 of FIG. 1 or FIG. 2 functions as power supply in the electrical circuit. FIG. 9 is a graph 900 of voltage-current characteristics of the semiconductor device 400 of FIG. 5, when functions as power supply in the electrical circuit.

The advantages of the present invention are disclosed as follows. The semiconductor device increases the amount of electrical energy produced from renewable energy source per total cost of manufacturing, installation and maintenance. The installation of the semiconductor device at different depths of non-resident fluid such as ocean and river water provide desired functional ability and energy generation at the same nominal rate, without the need to predict fluid hydrodynamics parameters. The semiconductor device increases efficiency in the extraction of energy per unit volume of water.

According to the present invention, the existence of non-zero velocity field in the electrolytic fluid stream at the interaction place of the semiconductor device ensures the energy conversion and power generation. The physical nature of the semiconductor device is configured to provide immunity to the harsh nature of the dynamic fluid. The semiconductor device body have no any inertial displacements, therefore, the depreciation rate is much lower than prior devices, based on faraday's law of induction. The present invention does not require energy storage devices such as batteries for electric energy consumption. The semiconductor device is compatible with landscape and marine transport because of its ability for installing on water bed. The present invention eliminates need of an integral part of rotating equipment such as generators and thereby avoids pollution.

The semiconductor device of the present invention eliminates the need of power transmission mechanism and power generator and converts of the kinetic energy of the fluid so that does not need to predict the dynamic behavior of the fluid such as mechanical parameters of ocean water. Further, the semiconductor device could be used in a variety of surface water such as oceans, rivers and lakes. The device of the present invention could also be used in any depth of water and sea bed where the size of the fluid velocity is minimum. The device is also configured to function in shallow water and sea bed without disturbing the natural landscape and marine transport.

In one embodiment, a plurality of semiconductor device of the present invention is interconnected in series and parallel arrays and deployed on an area of sea bed could in plate or carpet like form as shown in FIG. 7, thereby establishes a renewable energy farm to supply electricity for consumers located on the beach. The present invention also enables to supply electric power to gas and oil platforms established in oceans by construction of such renewable energy farms.

One aspect of the present disclosure is directed to a system for harvesting hydrokinetic energy. The system comprises a semiconductor device having a P-type semiconductor layer, a N-type semiconductor layer and a PN junction separating the P-type semiconductor layer and the N-type semiconductor layer. The device is configured to immerse in an electrolytic fluid stream such that the PN junction is adapted to be in contact with the electrolytic fluid stream having a non-zero velocity field, and the device induced by streaming potential at the solid-fluid interface enables conversion of kinetic energy of the fluid stream to electrical energy when the fluid stream impinges upon the device, at the vicinity of the PN junction. The system further comprises a conductive electrode embedded to the semiconductor device that is configured to conduct electrical energy generated by the semiconductor device.

Another aspect of the present disclosure is directed to a system for harvesting hydrokinetic energy. The system comprises a semiconductor device having a metal layer, a semiconductor layer and a Schottky contact separating the metal layer and the semiconductor layer. The device is configured to immerse in an electrolytic fluid stream such that the Schottky contact is adapted to be in contact with the electrolytic fluid stream having a non-zero velocity field, and the device induced by streaming potential at the solid-fluid interface enables conversion of kinetic energy of the fluid stream to electrical energy when the fluid stream impinges upon the device, at the vicinity of the Schottky contact. The system further comprises a conductive electrode connected to the semiconductor device to conduct electrical energy generated by the semiconductor device.

The system may further comprise an insulating layer. The conductive electrode may be coupled to an electrical load to receive the generated electrical energy. The system for harvesting hydrokinetic energy may further comprise an ammeter connected in series between the electrical load and the conductive electrode to measure the generated electrical energy. The electrolytic fluid stream may be sea water. The conductive electrode may be made of copper. The plurality of semiconductor devices may be configured to connect in series and parallel arrays. In certain examples, the metal layer is made of copper. The semiconductor layer may be a P-type semiconductor layer, or a N-type semiconductor layer. This semiconductor layer may be made of silicon carbide. The electrolytic fluid stream may be sea water. The plurality of semiconductor devices may be configured to connect in series and parallel arrays.

The foregoing description comprise illustrative embodiments of the present invention. Having thus described exemplary embodiments of the present invention, it should be noted by those skilled in the art that the within disclosures are exemplary only, and that various other alternatives, adaptations, and modifications may be made within the scope of the present invention. Merely listing or numbering the steps of a method in a certain order does not constitute any limitation on the order of the steps of that method.

Many modifications and other embodiments of the invention will come to mind to one skilled in the art to which this invention pertains having the benefit of the teachings presented in the foregoing descriptions. Although specific terms may be employed herein, they are used only in generic and descriptive sense and not for purposes of limitation. Accordingly, the present invention is not limited to the specific embodiments illustrated herein. While the above is a complete description of the preferred embodiments of the invention, various alternatives, modifications, and equivalents may be used. Therefore, the above description and the examples should not be taken as limiting the scope of the invention, which is defined by the appended claims.

1. A system for harvesting hydrokinetic energy, comprising:
a semiconductor device having a P-type semiconductor layer, a N-type semiconductor layer and a PN junction separating the P-type semiconductor layer and the N-type semiconductor layer,
wherein the semiconductor device is configured to immerse in a fluid stream such that the PN junction is adapted to be in contact with the fluid stream, as is found on Earth's surface water or any other kind of electrolytic fluid stream, having a non-zero velocity field,
wherein the semiconductor device induced by streaming potential at the solid-fluid interface enables conversion of kinetic energy of the fluid stream to electrical energy when the fluid stream impinges upon the semiconductor device, at the vicinity of the PN junction; and
a conductive electrode embedded to the semiconductor device is configured to conduct electrical energy generated by the semiconductor device.

2. The system of claim 1, wherein the system further comprises said insulating layer.

3. The system of claim 1, wherein the conductive electrode is coupled to an electrical load to receive the generated electrical energy.

4. The system of claim 1, further comprises an ammeter connected in series between the electrical load and the conductive electrode to measure the generated electrical energy.

5. The system of claim 1, wherein the fluid stream is sea water.

6. The system of claim 1, wherein the conductive electrode is made of copper.

7. A plurality of semiconductor device of claim 1 are configured to connect in series and parallel arrays.

8. A system for harvesting hydrokinetic energy, comprising:
a semiconductor device having a metal layer, a semiconductor layer and a Schottky contact separating the metal layer and the semiconductor layer,
wherein the semiconductor device is configured to immerse in a fluid stream such that the Schottky contact is adapted to be in contact with the fluid stream, as is found on Earth's surface water or any other kind of electrolytic fluid stream, having a non-zero velocity field, wherein the semiconductor device induced by streaming potential at the solid-fluid interface enables conversion of kinetic energy of the fluid stream to electrical energy when the fluid stream impinges upon the semiconductor device, at the vicinity of the Schottky contact; and
a conductive electrode connected to the semiconductor device to conduct electrical energy generated by the semiconductor device.

9. The system of claim 8, wherein the system further comprises said insulating layer.

10. The system of claim 8, wherein the conductive electrode is coupled to an electrical load to receive the generated electrical energy.

11. The system of claim 8, further comprises an ammeter connected in series between the electrical load and the conductive electrode to measure the generated electrical energy.

12. The system of claim 8, wherein the metal layer is made of copper.

13. The system of claim 8, wherein the semiconductor layer is a N-type silicon carbide.

14. The system of claim 8, wherein the electrolytic fluid stream is a sea water.

15. A plurality of semiconductor device of claim 8, configured to connect in series and parallel arrays.
